(19) United States
(12) Patent Application Publication
(10) Pub. No.: US 2017/0057808 A1
(43) Pub. Date: Mar. 2, 2017

(54) MEMS CHIP PACKAGE AND METHOD FOR MANUFACTURING THE SAME

(71) Applicant: Merry Electronics(Shenzhen) Co., Ltd., Guangdong (CN)

(72) Inventors: Chao-Sen Chang, Taichung (TW); Yung-Shiang Chang, Taichung (TW); Jen-Yi Chen, Taichung (TW); Chun-Chieh Wang, Taichung (TW)

(21) Appl. No.: 14/927,497

(22) Filed: Oct. 30, 2015

(30) Foreign Application Priority Data
Aug. 24, 2015 (TW) 104127564

(51) Int. Cl. B81B 7/00; B81C 1/00

(52) U.S. Cl. CPC B81B 7/007; B81C 1/00301; B81B 2201/0257; B81B 2207/015; B81B 2203/0315; B81B 2207/07; B81C 2203/0707; B81C 2203/0109

(57) ABSTRACT

Provided is a micro-electro-mechanical system (MEMS) chip package, including a circuit substrate, a MEMS chip, a driving chip, a cover, an insulator, and at least one first pad. The circuit substrate has a first surface and a second surface opposite to each other. The circuit substrate has a sound port passing through the first surface and the second surface. The MEMS chip is disposed on the first surface of the circuit substrate. The driving chip is electrically connected to the MEMS chip. The cover is disposed on the first surface of the circuit substrate. The cover covers the MEMS chip and the driving chip. The insulator covers the cover. The first pad is electrically connected to the driving chip by a first electrical path.

### CROSS-REFERENCE TO RELATED APPLICATION

This application claims the priority benefit of Taiwan application serial no. 104127564, filed on Aug. 24, 2015. The entirety of the above-mentioned patent application is hereby incorporated by reference herein and made a part of this specification.

### BACKGROUND OF THE INVENTION

Field of the Invention

The invention relates to a chip package and a method for manufacturing the same, and more particularly relates to a MEMS (Micro-Electro-Mechanical System) chip package and a method for manufacturing the same.

Description of Related Art

With progress of the technology, electronic products are developed to be lighter and smaller. Take microphones for example, MEMS chips have been widely used in this field. A traditional MEMS microphone package includes a MEMS chip, a driving chip for driving the MEMS chip, and a circuit board for carrying the MEMS chip and the driving chip. In addition to the aforementioned components, the traditional MEMS microphone package further includes a plurality of pads that can be electrically connected to other circuit boards. However, in a general bottom port MEMS microphone package, the pads and the sound port are disposed on the same side of the package. Therefore, when the MEMS microphone package is soldered to the other circuit boards, the solder between the pads may overflow to the sound port, resulting in low package yield.

In view of the above, how to maintain the sensitivity and frequency response of the bottom port MEMS microphone package while reducing the possibility of solder overflowing to the sound port to improve the yield rate of the MEMS chip package is an issue that needs to be addressed.

### SUMMARY OF THE INVENTION

The invention provides a MEMS chip package, which maintains the sensitivity and frequency response of a bottom port MEMS microphone package while reducing the possibility of solder overflowing to a sound port, so as to improve the yield rate of the MEMS chip package.

The invention provides a MEMS chip package, including a circuit substrate, a MEMS chip, a driving chip, a cover, an insulator, and at least one first pad. The circuit substrate has a first surface and a second surface opposite to each other. The circuit substrate has a sound port passing through the first surface and the second surface. The MEMS chip is disposed on the first surface of the circuit substrate. The driving chip is electrically connected to the MEMS chip. The cover is disposed on the first surface of the circuit substrate. The cover covers the MEMS chip and the driving chip. The insulator covers the cover. The first pad is electrically connected to the driving chip by a first electrical path.

In an embodiment of the invention, the MEMS chip package further includes a redistribution layer (RDL) disposed on the insulator.

In an embodiment of the invention, the cover is a conductive cover, for example. The conductive cover is electrically connected to the redistribution layer by a second electrical path. The second electrical path includes a via or a wire in the insulator.

In an embodiment of the invention, the first pad is disposed on the redistribution layer or the insulator.

In an embodiment of the invention, the number of the first pads is at least two, which are respectively disposed on the redistribution layer or the insulator.

In an embodiment of the invention, the MEMS chip includes a cavity corresponding to the sound port.

In an embodiment of the invention, the MEMS chip package further includes a wire. The driving chip is electrically connected to the MEMS chip via the wire.

In an embodiment of the invention, the first electrical path includes a conductive layer formed in the insulator.

In an embodiment of the invention, the conductive layer is a via or a wire, for example.

In an embodiment of the invention, the first electrical path further includes a conductive line formed in the circuit substrate.

In an embodiment of the invention, the driving chip is embedded in the circuit substrate and a distance is maintained between the driving chip and the sound port.

In an embodiment of the invention, the MEMS chip package further includes at least one second pad disposed on the second surface of the circuit substrate. The second pad is electrically connected to the corresponding first pad.

In an embodiment of the invention, the driving chip is an application specific integrated circuit (ASIC), for example.

In an embodiment of the invention, the MEMS chip is a sound sensing chip, for example.

The invention provides a manufacturing method for manufacturing a MEMS chip package, which includes the following steps. A circuit substrate having a first surface and a second surface opposite to each other is provided, wherein the circuit substrate includes a sound port passing through the first surface and the second surface. A MEMS chip is formed on the first surface of the circuit substrate. A driving chip is formed beside the MEMS chip. The driving chip is electrically connected to the MEMS chip. A cover is formed on the first surface of the circuit substrate. The cover covers the MEMS chip and the driving chip. An insulator is formed on the cover. At least one first pad is formed on the insulator. The first pad is electrically connected to the driving chip by a first electrical path.

In an embodiment of the invention, a forming method of the first electrical path includes the following steps. A via opening is formed in the insulator after forming the insulator on the cover, wherein the via opening passes through the insulator. A conductive material is filled into the via opening to form a via to electrically connect the first pad and a conductive line in the circuit substrate.

In an embodiment of the invention, a forming method of the via opening includes mechanical drilling, laser drilling, or a combination of the foregoing, for example.

In an embodiment of the invention, the forming method of the first electrical path includes the following steps. A wire is formed to electrically connect the cover and a conductive line in the circuit substrate before forming the insulator on the cover. The insulator is formed on the cover to overlay the wire. A portion of the insulator and a portion of the wire are removed to divide the wire into two parts. One of the two parts is electrically connected to the first pad and the conductive line in the circuit substrate.

In an embodiment of the invention, a method of removing the portion of the insulator and the portion of the wire includes chemical mechanical polishing (CMP) process.

Based on the above, in the MEMS chip package of the invention, the first pad is disposed on the cover by sidewall routing (i.e. the via or wire in the insulator). Therefore, the invention not only maintains the sensitivity and frequency response of the bottom port MEMS chip package but also reduces the possibility of solder overflowing to the sound port, so as to improve the yield rate of the MEMS chip package.

In addition, the MEMS chip package of the invention further includes a conductive cover, which covers the MEMS chip and the driving chip, so as to achieve favorable electromagnetic interference (EMI) shielding.

To make the aforementioned and other features and advantages of the invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate exemplary embodiments of the invention and, together with the description, serve to explain the principles of the invention.

FIG. 1A through FIG. 1C are schematic cross-sectional views showing a method for manufacturing a MEMS chip package according to the first embodiment of the invention.

FIG. 2A through FIG. 2C are schematic cross-sectional views showing a method for manufacturing a MEMS chip package according to the second embodiment of the invention.

FIG. 3 is a schematic view of a MEMS chip package according to the third embodiment of the invention.

FIG. 4 is a schematic view of a MEMS chip package according to the fourth embodiment of the invention.

### DESCRIPTION OF THE EMBODIMENTS

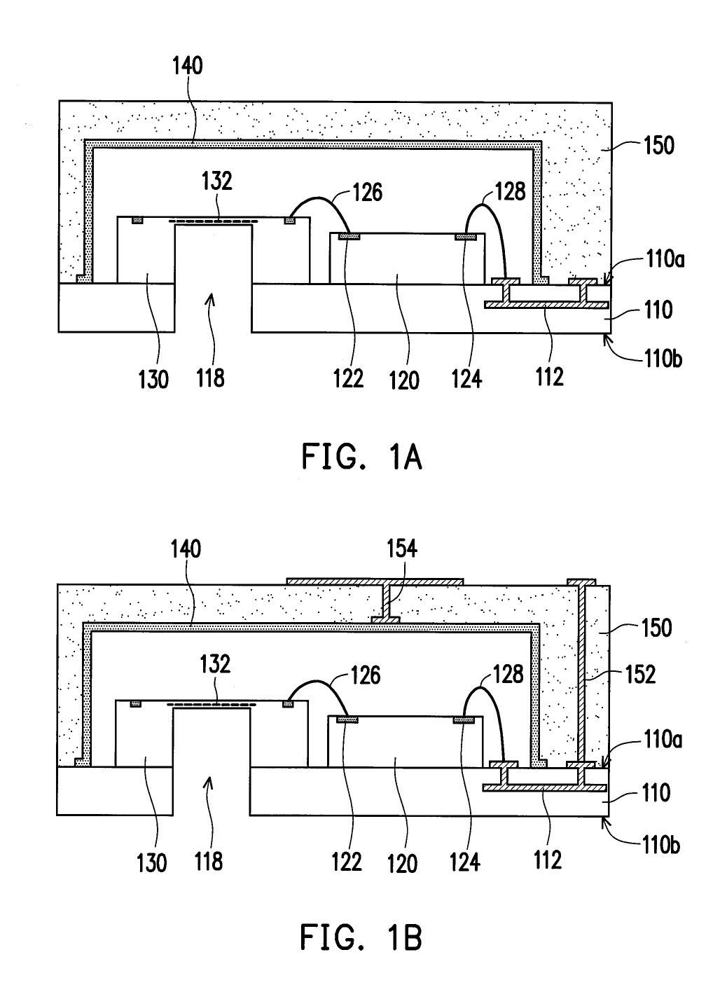

FIG. 1A through FIG. 1C are schematic cross-sectional views showing a method for manufacturing a MEMS chip package according to the first embodiment of the invention.

With reference to FIG. 1A, this embodiment provides a method for manufacturing a MEMS chip package 100a, which includes the following steps. A circuit substrate 110 having a first surface 110a and a second surface 110b opposite to each other is provided. The circuit substrate 110 has a conductive line 112. In an embodiment, the circuit substrate 110 is a printed circuit board including a plurality of patterned conductive line layers, for example. A material of the patterned conductive line layers includes a metal material, which may be gold, copper, silver, palladium, aluminum, or a combination of the foregoing, for example. In this embodiment, the patterned conductive line layer may be deemed as the conductive line of the circuit substrate 110, which may be designed according to the required circuit layout. In addition, the circuit substrate 110 further has a sound port 118 that extends (or passes through) from the first surface 110a to the second surface 110b.

Thereafter, a MEMS chip 130 is formed on the first surface 110a of the circuit substrate 110. In an embodiment, the MEMS chip 130 is a sound sensing chip, for example. In this embodiment, the MEMS chip 130 has a cavity 132. The cavity 132 includes a back plate and a diaphragm, wherein a gap is maintained between the back plate and the diaphragm. The MEMS chip 130 is capable of converting vibration energy of a sound into an electrical signal, and the electrical signal generated by the MEMS chip 130 may be read via a wire 126, a driving chip 120, a wire 128, and the conductive line 112 in the circuit substrate 110. In this embodiment, the cavity 132 corresponds to the sound port 118, which may be deemed as a bottom port MEMS chip package. Generally, compared to a top port MEMS chip package, the bottom port MEMS chip package is favorable in terms of sensitivity and frequency response.

Next, the driving chip 120 is formed beside the MEMS chip 130. Specifically, the driving chip 120 is also disposed on the first surface 110a of the circuit substrate 110. The driving chip 120 has electrodes 122 and 124. The driving chip 120 is electrically connected to the MEMS chip 130 by the electrode 122 and the wire 126 and electrically connected to the conductive line 112 in the circuit substrate 110 by the electrode 124 and the wire 128. In an embodiment, a material of the wires 126 and 128 is gold, copper, silver, palladium, aluminum, or a combination of the foregoing, for example. In an embodiment, the driving chip 120 is an application specific integrated circuit (ASIC), for example. In an embodiment, the electrode 122 is a signal input electrode and the electrode 124 is a signal output electrode, for example.

Moreover, in other embodiments, the MEMS chip 130 may be electrically connected to the circuit substrate 110 and the driving chip 120 via a conductive bump and the conductive line by flip-chip bonding (not shown). In an embodiment, the conductive bump is a solder bump, a gold bump, or a polymer conductive bump, for example. Nevertheless, the invention is not limited thereto.

Then, a cover 140 is formed on the first surface 110a of the circuit substrate 110. The cover 140 covers the MEMS chip 130 and the driving chip 120. The cover 140 may be a conductive cover, for example, and this conductive cover may be grounded via a patterned conductive line layer (not shown) in the circuit substrate 110, so as to shield noise and electromagnetic interference. In an embodiment, a material of the conductive cover is gold, copper, silver, palladium, aluminum, or a combination of the foregoing, for example.

Thereafter, an insulator 150 is formed to cover a portion of the first surface 110a of the circuit substrate 110, a portion of the conductive line 112, and the cover 140. In an embodiment, the insulator 150 includes a molding compound, which may be silicone resin, epoxy resin, or a combination of the foregoing, for example. A forming method of the insulator 150 includes spin-coating, lamination, or deposition, for example.

With reference to FIG. 1B, vias 152 and 154 are formed in the insulator 150. Specifically, via openings (not shown) are formed in the insulator 150 first. One of the via openings passes through the insulator 150 and exposes a portion of a surface of the conductive line 112. The other of the via openings passes through the insulator 150 and exposes a portion of a surface of the cover 140. Thereafter, a conductive material is filled into the via openings to form the vias 152 and 154. In an embodiment, the vias 152 and 154 may be deemed as conductive layers formed in the insulator 150. In an embodiment, a forming method of the via openings includes mechanical drilling, laser drilling, or a combination of the foregoing, for example. In an embodiment, the conductive material is gold, copper, silver, palladium, aluminum, or a combination of the foregoing, for example.

With reference to FIG. 1C, a redistribution layer 160 and first pads 170a and 170b are formed sequentially on the insulator 150. The redistribution layer 160 is disposed between the first pads 170a and 170b and the insulator 150. The redistribution layer 160 has a plurality of patterned conductive line layers and a plurality of contact pads (not shown) for redistributing the positions of the first pads 170a and 170b thereon. The first pad 170a may be electrically connected to the driving chip 120 via the via 152, the conductive line 112, and the wire 128. In this embodiment, the via 152, the conductive line 112, and the wire 128 may be deemed as a first electrical path. Furthermore, the cover 140 may also be electrically connected to the redistribution layer 160 via the via 154, such that the cover 140 is grounded via the redistribution layer 160 to achieve the effect of shielding electromagnetic interference. In this embodiment, the via 154 may be deemed as a second electrical path. In an embodiment, the redistribution layer 160 may be one layer or include two or more layers, for example, which may be designed according to the required circuit layout. Nevertheless, the invention is not limited thereto. In other embodiments, the redistribution layer 160 may be omitted. In other words, the first pads 170a and 170b may be directly disposed on the insulator 150. Although FIG. 1C illustrates two first pads 170a and 170b, the invention is not limited thereto. The number of the first pads may be one, two, or more, for example, which may be designed according to the required circuit layout. In an embodiment, a material of the first pads 170a and 170b is gold, copper, silver, palladium, aluminum, or a combination of the foregoing, for example.

It should be noted that, in the MEMS chip package 100a of this embodiment, the first pad 170a is disposed on the cover 140 through the first electrical path (i.e. the via 152, the conductive line 112, and the wire 128). Therefore, this embodiment not only maintains the sensitivity and frequency response of the bottom port MEMS chip package 100a but also reduces the possibility of solder overflowing to the sound port, so as to improve the yield rate of the MEMS chip package 100a. In addition, the MEMS chip package 100a of this embodiment further includes the cover 140, which covers the MEMS chip 130 and the driving chip 120, so as to achieve favorable electromagnetic interference (EMI) shielding.

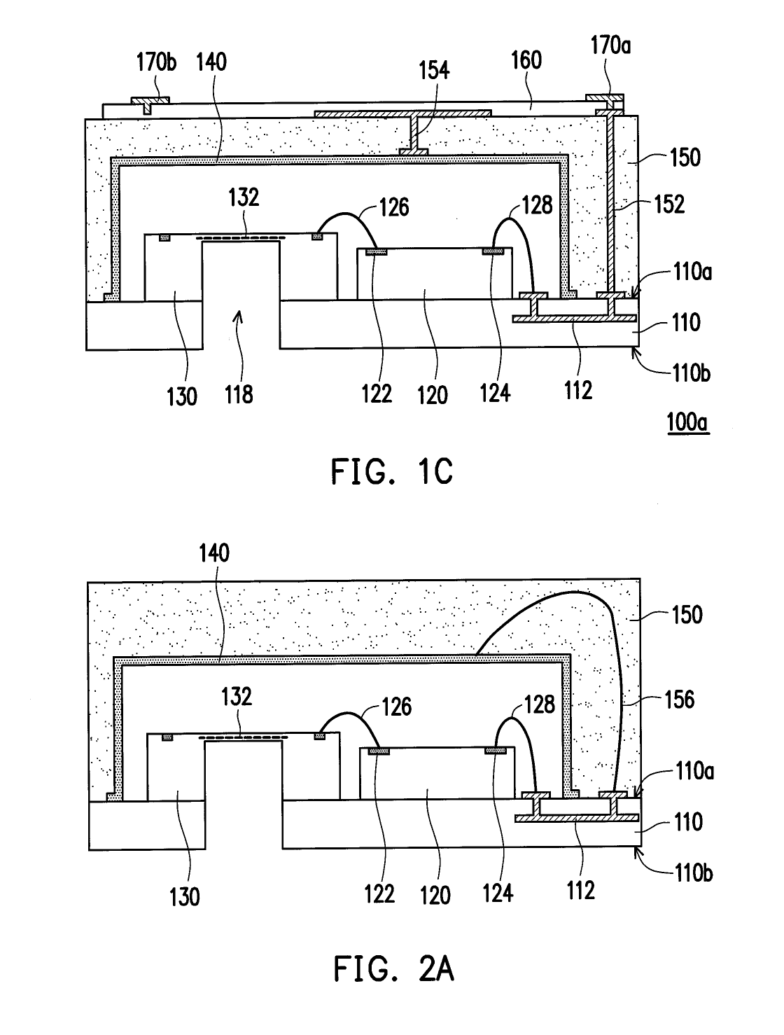

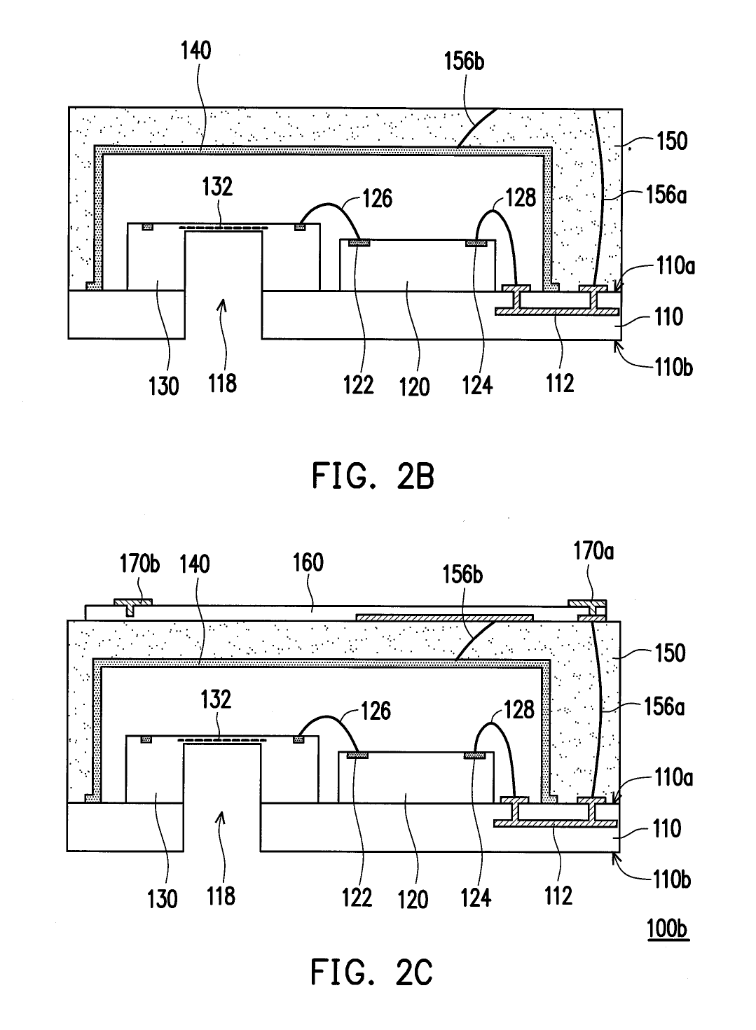

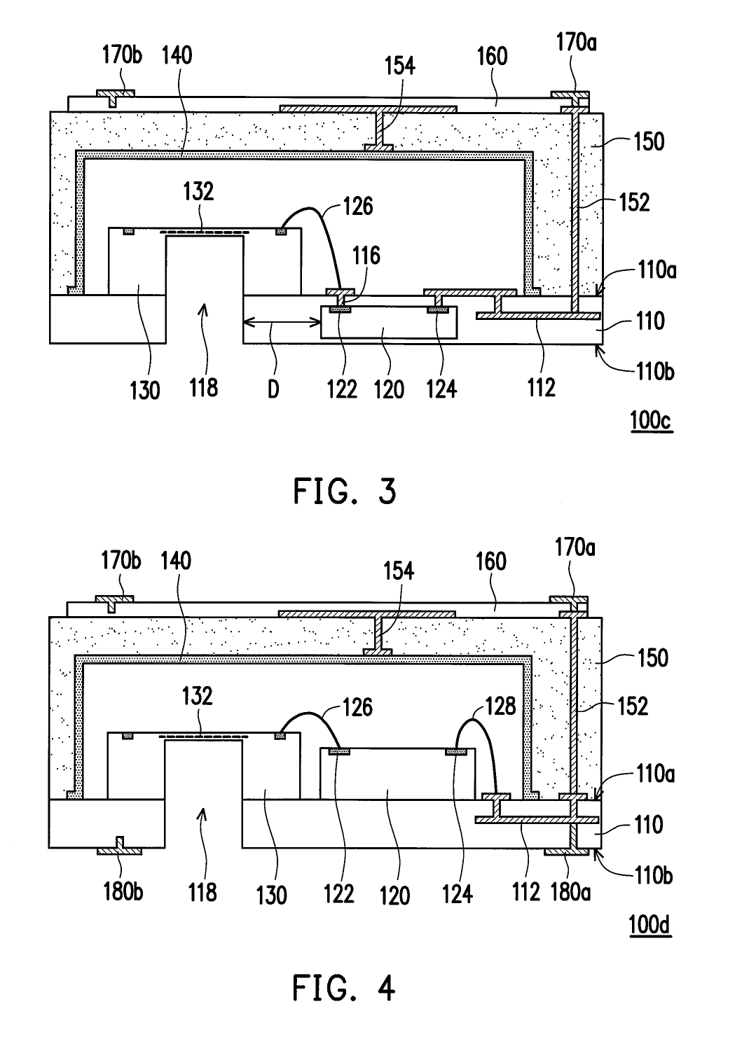

In the following embodiments, the same or similar elements, components, or layers are represented by similar reference numerals. For example, the circuit substrate 110 of FIG. 1A, the circuit substrate 110 of FIG. 2A, the circuit substrate 110 of FIG. 3, and the circuit substrate 110 of FIG. 4 are the same or similar components. Thus, details thereof are not repeated again.

FIG. 2A through FIG. 2C are schematic cross-sectional views showing a method for manufacturing a MEMS chip package according to the second embodiment of the invention.

With reference to FIG. 2A, this embodiment provides another method for manufacturing a MEMS chip package 100b, which includes the following steps. The forming methods, materials, and connection relationship of the circuit substrate 110, the conductive line 112, the driving chip 120, the wires 126 and 128, the MEMS chip 130, and the cover 140 in FIG. 2A are similar to those shown in FIG. 1A and thus are not repeated hereinafter. As shown in FIG. 2A, a wire 156 is formed before the insulator 150 is formed on the cover 140, so as to electrically connect the cover 140 and the conductive line 112 in the circuit substrate 110. Then, the insulator 150 is formed to cover a portion of the first surface 110a of the circuit substrate 110, a portion of the conductive line 112, the cover 140, and the wire 156. In an embodiment, a material of the wire 156 is gold, copper, silver, palladium, aluminum, or a combination of the foregoing, for example.

With reference to FIG. 2B, a portion of the insulator 150 and a portion of the wire 156 are removed to expose a surface of the wire 156. The removing step divides the wire 156 into two parts 156a and 156b (i.e. two wires 156a and 156b). In an embodiment, a method for removing the portion of the insulator 150 and the portion of the wire 156 includes chemical mechanical polishing (CMP) process, for example. In an embodiment, the wires 156a and 156b may be deemed as conductive layers formed in the insulator 150.

With reference to FIG. 2C, the redistribution layer 160 and first pads 170a and 170b are formed sequentially on the insulator 150. The redistribution layer 160 is disposed between the first pads 170a and 170b and the insulator 150. The first pad 170a of the MEMS chip package 100b may be electrically connected to the driving chip 120 via the wire 156a, the conductive line 112, and the wire 128. In this embodiment, the wire 156a, the conductive line 112, and the wire 128 may be deemed as the first electrical path. Furthermore, the cover 140 may also be electrically connected to the redistribution layer 160 via the wire 156b, such that the cover 140 is grounded via the redistribution layer 160 to achieve the effect of shielding electromagnetic interference. In this embodiment, the wire 156b may be deemed as the second electrical path.

FIG. 3 is a schematic view of a MEMS chip package according to the third embodiment of the invention.

With reference to FIG. 3, a MEMS chip package 100c of the third embodiment of the invention is basically similar to the MEMS chip package 100a of the first embodiment of the invention. A difference therebetween lies in that: the driving chip 120 of FIG. 3 is embedded in the circuit substrate 110. The driving chip 120 is electrically connected to the MEMS chip 130 via the electrode 122, a conductive line 116, and the wire 126. Moreover, the driving chip 120 is further electrically connected to the first pad 170a via the electrode 124, the conductive line 112, and the via 152. It should be noted that the via 152 not only passes through the insulator 150 but further extends through a portion of the circuit substrate 110 to be electrically connected to the conductive line 112 in the circuit substrate 110.

In addition, because the driving chip 120 is completely embedded in the circuit substrate 110, a specific distance D is maintained between the driving chip 120 and the sound port 118 of the circuit substrate 110. The distance D ensures that the driving chip 120 is not exposed outside the circuit substrate 110 and provides the driving chip 120 adequate protection.

FIG. 4 is a schematic view of a MEMS chip package according to the fourth embodiment of the invention.

With reference to FIG. 4, a MEMS chip package 100d of the fourth embodiment of the invention is basically similar to the MEMS chip package 100a of the first embodiment of the invention. A difference therebetween lies in that: the MEMS chip package 100d of the fourth embodiment further includes a plurality of second pads 180a and 180b disposed on the second surface 110b of the circuit substrate 110. The second pad 180a is electrically connected to the corresponding first pad 170a. Although the cross-sectional view of FIG. 4 does not illustrate the connection between the second pad 180b and the first pad 170b, it should be understood that the second pad 180b may be electrically connected to the first pad 170b by wire routing. The MEMS chip package 100d of the fourth embodiment includes the first pads 170a and 170b disposed on the first surface 110a and the second pads 180a and 180b disposed on the second surface 110b. When the MEMS chip package 100d is bonded to other circuit boards, the other circuit boards may be bonded to the first pads 170a and 170b or the second pads 180a and 180b flexibly to meet the user's needs.

It will be apparent to those skilled in the art that various modifications and variations can be made to the disclosed embodiments without departing from the scope or spirit of the invention. In view of the foregoing, it is intended that the invention covers modifications and variations provided that they fall within the scope of the following claims and their equivalents.

1. A micro-electro-mechanical system (MEMS) chip package, comprising:
a circuit substrate having a first surface and a second surface opposite to each other and a sound port passing through the first surface and the second surface;
a MEMS chip disposed on the first surface of the circuit substrate;
a driving chip electrically connected to the MEMS chip;
a cover disposed on the first surface of the circuit substrate and covering the MEMS chip and the driving chip;
an insulator covering the cover; and
at least one first pad disposed over the insulator and electrically connected to the driving chip by a first electrical path.

2. The MEMS chip package according to claim 1, further comprising a redistribution layer disposed on the insulator.

3. The MEMS chip package according to claim 2, wherein the cover is a conductive cover, which is electrically connected to the redistribution layer by a second electrical path, wherein the second electrical path comprises a via or a wire in the insulator.

4. The MEMS chip package according to claim 2, wherein the first pad is disposed on the redistribution layer or the insulator.

5. The MEMS chip package according to claim 2, wherein the number of the first pads is at least two, which are respectively disposed on the redistribution layer or the insulator.

6. The MEMS chip package according to claim 1, wherein the MEMS chip comprises a cavity corresponding to the sound port.

7. The MEMS chip package according to claim 1, further comprising a wire, wherein the driving chip is electrically connected to the MEMS chip via the wire.

8. The MEMS chip package according to claim 1, wherein the first electrical path comprises a conductive layer formed in the insulator.

9. The MEMS chip package according to claim 8, wherein the conductive layer is a via or a wire.

10. The MEMS chip package according to claim 8, wherein the first electrical path further comprises a conductive line formed in the circuit substrate.

11. The MEMS chip package according to claim 1, wherein the driving chip is embedded in the circuit substrate and a distance is maintained between the driving chip and the sound port.

12. The MEMS chip package according to claim 1, further comprising at least one second pad disposed on the second surface of the circuit substrate, wherein the second pad is electrically connected to the corresponding first pad.

13. The MEMS chip package according to claim 1, wherein the driving chip comprises an application specific integrated circuit.

14. The MEMS chip package according to claim 1, wherein the MEMS chip comprises a sound sensing chip.

15. A manufacturing method of a MEMS chip package, comprising:
providing a circuit substrate having a first surface and a second surface opposite to each other, wherein the circuit substrate comprises a sound port passing through the first surface and the second surface;
forming a MEMS chip on the first surface of the circuit substrate;
forming a driving chip beside the MEMS chip, wherein the driving chip is electrically connected to the MEMS chip;
forming a cover on the first surface of the circuit substrate, wherein the cover covers the MEMS chip and the driving chip;
forming an insulator on the cover; and
forming at least one first pad on the insulator, wherein the first pad is electrically connected to the driving chip by a first electrical path.

16. The manufacturing method according to claim 15, wherein a forming method of the first electrical path comprises:
forming a via opening in the insulator after forming the insulator on the cover, wherein the via opening passes through the insulator; and
filling a conductive material into the via opening to form a via to electrically connect the first pad and a conductive line in the circuit substrate.

17. The manufacturing method according to claim 16, wherein a forming method of the via opening comprises mechanical drilling, laser drilling, or a combination of the foregoing.

18. The manufacturing method according to claim 15, wherein the forming method of the first electrical path comprises:
forming a wire to electrically connect the cover and a conductive line in the circuit substrate before forming the insulator on the cover;
forming the insulator on the cover to overlay the wire; and
removing a portion of the insulator and a portion of the wire to divide the wire into two parts, wherein one of the two parts is electrically connected to the first pad and the conductive line in the circuit substrate.

19. The manufacturing method according to claim 18, wherein a method of removing the portion of the insulator and the portion of the wire comprises chemical mechanical polishing (CMP) process.

20. The MEMS chip package according to claim 1, wherein the sound port is disposed at a bottom side of the MEMS chip package, the first pad is disposed at a top side of the MEMS chip package, and the bottom side and the top side are different from and opposite to each other.
